(19) United States
(12) Patent Application Publication
(10) Pub. No.: US 2019/0354148 A1
(43) Pub. Date: Nov. 21, 2019

(54) CONDUCTING HEAT THROUGH A HINGE

(71) Applicant: Microsoft Technology Licensing, LLC, Redmond, WA (US)

(72) Inventors: Andrew Douglas DELANO, Woodinville, WA (US); Erin Elizabeth HURBI, San Francisco, CA (US); Lincoln Matthew GHIONI, Redmond, WA (US)

(73) Assignee: Microsoft Technology Licensing, LLC, Redmond, WA (US)

(21) Appl. No.: 15/982,892

(22) Filed: May 17, 2018

(51) Int. Cl. G06F 1/20; H05K 7/20; G02B 27/01; F28D 15/04

(52) U.S. Cl. CPC G06F 1/203; H05K 7/2099; H05K 7/20336; G06F 1/1616; F28D 15/04; G06F 2200/201; G06F 2200/203; G02B 27/0176

(57) ABSTRACT

Examples are disclosed that relate to heat transfer devices comprising a vapor chamber and a flexible hinge. One disclosed example provides an electronic device comprising a first portion and a second portion connected by a hinge region, and a vapor chamber extending from the first portion to the second portion across the hinge region, the vapor chamber comprising a first layer comprising titanium, a second layer comprising titanium joined to the first layer to form the vapor chamber, a working fluid within the vapor chamber, and a third layer comprising titanium positioned between the first layer and the second layer, the third layer comprising one or more features configured to conduct the working fluid via capillary action.

### BACKGROUND

Heat pipes and vapor chambers are commonly used in electronic devices to transfer heat away from heat-producing components. Both heat pipes and vapor chambers include a chamber with a working fluid and a wicking structure, but differ in that the chamber of a heat pipe is formed within a pipe, whereas a vapor chamber is formed from sealing plate-like structures together to form the chamber. Heat from a heat-producing component evaporates the working fluid at an evaporator of the heat pipe or vapor chamber. The vapor-phase working fluid travels along the chamber to a condenser, where it transitions back to a liquid phase, thereby releasing the heat. The liquid phase is then transported back to the evaporator via capillary action of the wicking structure, gravity, and/or other suitable mechanism.

### SUMMARY

Examples are disclosed that relate to transferring heat between regions of a device connected by a hinge. One disclosed example provides an electronic device comprising a first portion and a second portion connected by a hinge region, and a vapor chamber extending from the first portion to the second portion across the hinge region, the vapor chamber comprising a first layer comprising titanium, a second layer comprising titanium, the second layer being joined to the first layer to form the vapor chamber, a working fluid within the vapor chamber, and a third layer comprising titanium positioned between the first layer and the second layer, the third layer comprising one or more features configured to conduct the working fluid via capillary action.

Another example provides an electronic device, comprising a first portion and a second portion connected by a hinge region, and a vapor chamber extending from the first portion to the second portion, the vapor chamber comprising a torsional hinge connecting a first vapor chamber portion and a second vapor chamber portion.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 schematically illustrates a laptop computer comprising an example vapor chamber having a corrugated hinge region.

FIG. 2 shows the laptop computer of FIG. 1 in a closed configuration.

FIG. 3 illustrates an example head-mounted display device that may utilize a vapor chamber extending through a hinge region.

FIG. 4 illustrates an exploded view of an example vapor chamber having a corrugated hinge region.

FIG. 5 shows a view of an example vapor chamber having a Ni/Ti alloy hinge region.

FIG. 6 shows a section view of the vapor chamber of FIG. 4.

FIG. 7 shows another sectional view of the vapor chamber of FIG. 4.

FIG. 8 shows another example vapor chamber comprising bending features formed in layers of the vapor chamber.

FIGS. 9-11 show another example vapor chamber comprising a torsional hinge region defining a continuous chamber.

### DETAILED DESCRIPTION

Various devices may include different portions separated by a hinge. For example, a hinge may separate a screen portion and a base portion of a laptop computing device. Much of the heat produced by the laptop may be generated by components located in the base portion, while the screen portion may provide an effective surface area for passive heat transfer. However, transferring heat from the base portion of the laptop to the screen portion across the hinge for dissipation may be difficult. As one example, a single-phase heat transfer device comprising a material such as graphite or copper may be used to transfer heat through the hinge region. However, such mechanisms may not transfer sufficient amounts of heat for effective device cooling, and may suffer from fatigue or deformation through repeated flexing.

As another example, a vapor chamber or heat pipe (referred to herein collectively by the term “vapor chamber”) may be used to conduct heat across a hinged joint. While vapor chambers generally transfer heat rapidly and efficiently, routing a vapor chamber through a hinged region of a device may pose challenges. For example, a vapor chamber may function poorly if a cross-section area of the vapor chamber becomes obstructed while bending the vapor chamber, or if the path of the vapor is impeded by ribs or other such internal structures in the hinged region. Further, vapor chambers are often formed from copper metal, which may fatigue, deform, and eventually fail due to bending cycles as the hinge is repeatedly moved.

Thus, examples are disclosed that relate to vapor chambers having a flexible hinge region configured to withstand repeated bending cycles, and to maintain a desired cross-sectional area of a vapor chamber within a hinge region of a device as the hinged parts are moved relative to one another. In one example, a vapor chamber comprises a corrugated section structure configured to allow flexing while maintaining a desired vapor chamber cross-sectional area. Such a vapor chamber may be formed from titanium metal, which is lightweight, has good thermal conductivity and is resistant to damage from bending, even over many bending cycles. In another example, the flexible hinge region comprises a nickel-titanium (Ni/Ti) alloy material used to form the layers of the vapor chamber in the hinge region, as such alloys may be highly bendable even when not formed in a corrugated shape, yet resistant to fatigue over many bending cycles. Titanium and Ni/Ti alloys also may possess other advantageous properties, as described in more detail below. In yet other examples, a vapor chamber may comprise a torsional hinge. In any of these examples, the resulting vapor chamber may comprise a continuous, or living, hinge that maintains a free path for vapor and liquid phases across the hinge. The resulting structure may be positioned within the interior of a device hinge, or even may act as the device hinge itself in some examples.

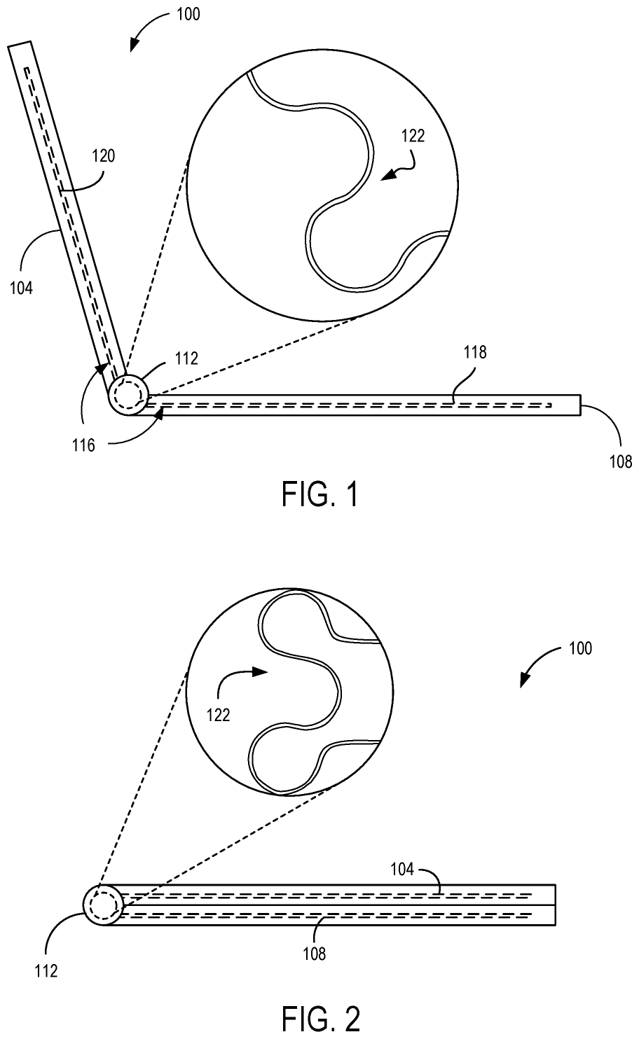

A vapor chamber according to the present disclosure may be used in many different types of devices. As one example, a vapor chamber according to the present disclosure may be incorporated into a laptop computing device. FIG. 1 schematically illustrates an example of a laptop computing device 100 comprising a screen portion 104 and a base portion 108 connected to the screen portion 104 via a hinge 112. Dashed lines schematically illustrate a vapor chamber 116 incorporated into the laptop computing device 100. In this example, the vapor chamber 116 comprises an evaporator 118 located in base portion 108, and a condenser 120 located in screen portion 104. In this example, the vapor chamber 116 includes a corrugated structure 122 located within hinge 112 to allow the vapor chamber to resiliently flex in the hinge region as the hinge is moved. FIG. 1 illustrates the laptop 100 in an open configuration. In the illustrated configuration, the screen portion 104 and the base portion 108 of the laptop 100 are oriented at an angle of approximately 120 degrees about the hinge 112. In contrast, FIG. 2 shows the laptop computing device 100 in a closed configuration. In this configuration, the screen portion 104 and the base portion 108 are parallel. As schematically shown in the cutouts of the hinge region, the corrugations of the vapor chamber 116 in the closed configuration of FIG. 2 have a relatively more compressed state on an inner side of the curvature of the hinge, and a relatively more expanded state on an outer side of the curvature of the hinge, as compared to FIG. 1. In the configurations of both FIG. 1 and FIG. 2, the corrugations allow the vapor chamber to bend along with the hinge angle while maintaining suitable vapor chamber dimensions for device cooling. While described herein in the context of a hinged computing device, the disclosed examples may be used in any suitable device (e.g. satellites).

As mentioned above, the use of titanium or Ni/Ti alloys may provide various advantages compared to other materials for a vapor chamber with a flexible hinge region. For example, many conventional vapor chambers are made of copper. Copper is more malleable than titanium, and thus may be less resistant to fatigue and damage from repeated bending cycles. The use of a thinner layer of copper may facilitate the formation of a flexible hinge region in such a vapor chamber. However, a thin layer of copper may allow an undesirable quantity of air to diffuse through the copper and into the vapor chamber over time, which may decrease a lifetime of the vapor chamber. The use of a thicker layer may help to slow the rate of air diffusion, but also may add undesirable weight and may render the vapor chamber more prone to damage from multiple flexing cycles.

In contrast, a thin sheet of titanium or Ni/Ti alloy may form a more robust barrier to air diffusion than a similarly thin sheet of copper, as a titanium oxide layer exists on the surface that may provide a better barrier against air diffusion. Further, as mentioned above, a sheet of titanium metal (e.g. a 100 μm thick sheet) may be stronger and less prone to fatigue than a comparable sheet of copper metal. Additionally, titanium has a high strength-to-weight ratio. As such, a thin layer of titanium may be stronger and more damage resistant than copper, thereby helping to reduce device weight compared to the use of a copper vapor chamber.

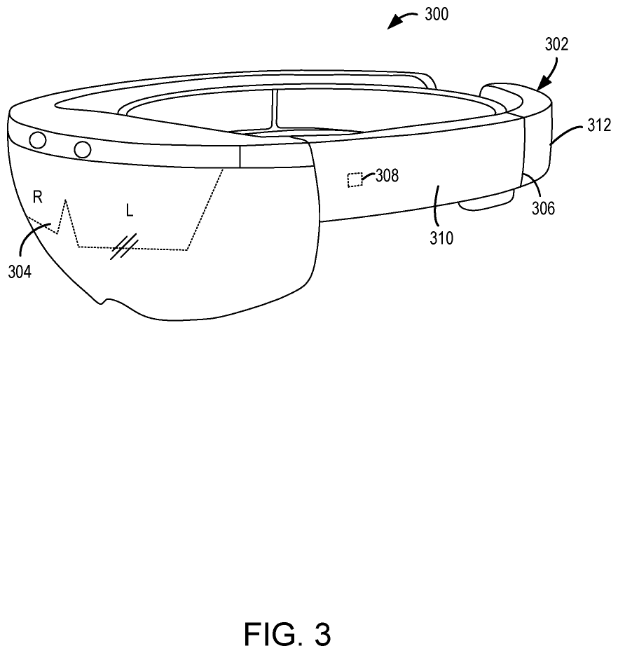

FIG. 3 illustrates another example device in which a vapor chamber according to the present disclosure may be used. In this example, a head-mounted display (HMD) device 300 includes a frame 302 configured to surround a head of a user to position a display 304 close to the user's eyes. The frame 306 of the HMD device 300 further comprises a hinge 310 to accommodate different head sizes. In this example, heat-producing components, such as a processor 308, may be located on one side of the hinge, while the other side 314 may have good characteristics for dissipating heat produced by the heat-producing components. As such, a vapor chamber with a flexible hinge portion may be used to span the hinge region of the HMD device 304 for transferring heat to the adjustable portion of the frame.

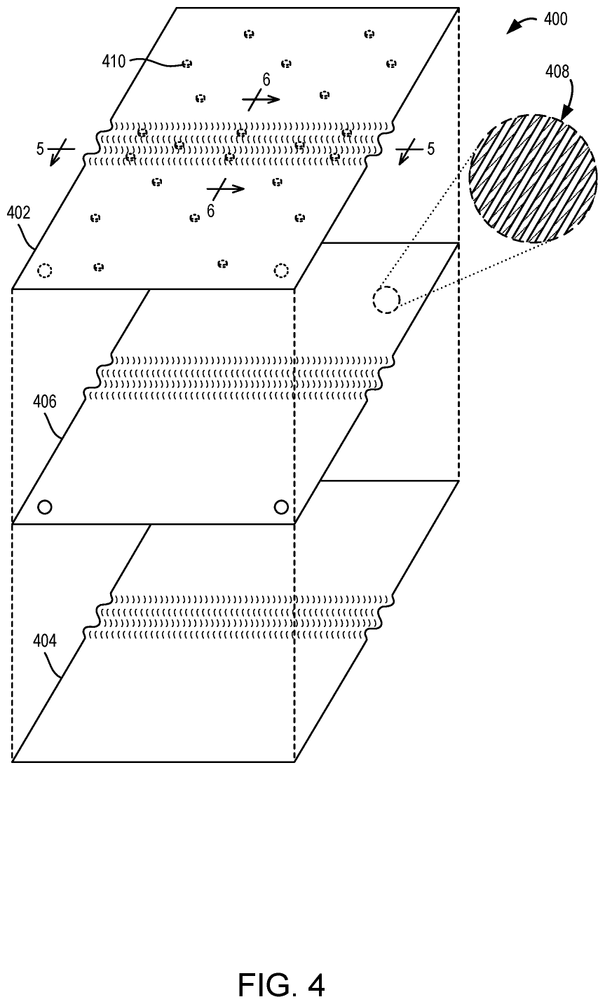

FIG. 4 shows an exploded view of an example vapor chamber 400. While depicted as having a rectangular configuration, a vapor chamber according to the present disclosure may have any suitable configuration to fit within a desired device. Vapor chamber 400 comprises a first layer 402 and a second layer 404. In some examples, each of these structures may be formed from a thin (e.g. 100 μm) sheet of titanium. The first layer 402 and the second layer 404 may be welded around the perimeter of the vapor chamber 400 to form a hermetically sealed vapor chamber containing a working fluid (not shown). Further, vapor chamber 400 also comprises a third layer 406 positioned between the first layer 402 and the second layer 404. The third layer 406 is configured to provide a wicking structure for transporting the working fluid in a liquid phase from the condenser to the evaporator via capillary action. In this example, the third layer comprises a plurality of etched channels 408 running between the condenser and evaporator, as illustrated in the magnified cutout.

The etched channels 408 of the third layer 406, which may extend a full thickness of the third layer, may be formed in titanium using photolithographic techniques. In some examples, the etched channels 408 may have a width of approximately 50 microns. The third layer 406 comprising the etched channels 408 may be placed in close proximity to the second layer 404, e.g. by tack welding the third layer 406 to the second layer 404 at various locations around a perimeter of the second and third layers 404, 406. The combination of the proximity of the third layer 406 and the second layer 404, together with the etched channels 408 of the third layer 406, allow wicking of water or other working fluid (e.g. ammonia, ethanol) from the condenser to the evaporator to occur.

The use of the third layer 406 may simplify fabrication of the vapor chamber 400 compared to forming wicking structures directly in the first layer 402 and/or second layer 404. For example, the etching of wicking structures directly in the second layer 404 or first layer 402 may be difficult, as the lithographic etching of titanium tends to form undercuts beneath photoresist structures. As such, it can be difficult to form channels of sufficient depth that also include a sufficiently narrow width for wicking (e.g. a depth to width ratio of 10:1 may be used in some vapor chambers).

Continuing with FIG. 4, the vapor chamber 400 also comprises a plurality of spacers 414 configured to maintain a desired spacing between the first layer 402 and the second and third layers 404, 406. The spacers 414 may be arranged with sufficient sparsity at not to impede vapor flow to an unsuitable degree, yet with sufficient density to support the vapor chamber against deformation from external air pressure and bending in the hinge region.

Heap pipe 400 may be formed in any suitable manner. As one example, spacers 414 and channels 408 may first be formed via lithographic etching of titanium sheets (or Ni/Ti sheets), e.g. using methods similar to those employed in semiconductor integrated circuit manufacturing. In other examples, spacers 141 may be separate structures from the titanium sheet, and attached to the sheet in a separate process via welding or other suitable method. After forming such structures, for a vapor chamber comprising a corrugated hinge region, the hinge region may be formed by bending each layer into a desired corrugated configuration. Next, the third layer may be tacked welded or otherwise joined to desired locations of the first and/or second layers. Then, the first layer and the second layer may be welded around most of the perimeter of the layers to form the vapor chamber, while leaving an opening through which to add the working fluid. The working fluid may be added to the vapor chamber and heated to form a vapor that displaces air. The vapor chamber then may be completely sealed via welding, such that cooling and condensation of the working fluid vapor forms the desired vacuum within the vapor chamber.

Each of the first layer, second layer, and third layer may have any suitable thickness. Suitable thicknesses for the first and second layer include thicknesses on the order of 100-500 microns. In a more specific example, the first layer may have a thickness of approximately 400 microns, the second layer may have a thickness of approximately 130 microns, and the third layer may include a thickness on the order of 50 microns. Further, in some examples, the second layer also may include etched channels having dimensions, for example on the order of 250 microns wide and 100 microns deep. The corrugations likewise may have any suitable configuration. In some examples, each corrugation may have a bend radius equal to or greater than ten times the thickness of the vapor chamber. The overall thickness of the vapor chamber may be on the order of 500 microns in some examples. In other examples, the individual layers and vapor chamber formed therefrom may have any other suitable dimensions.

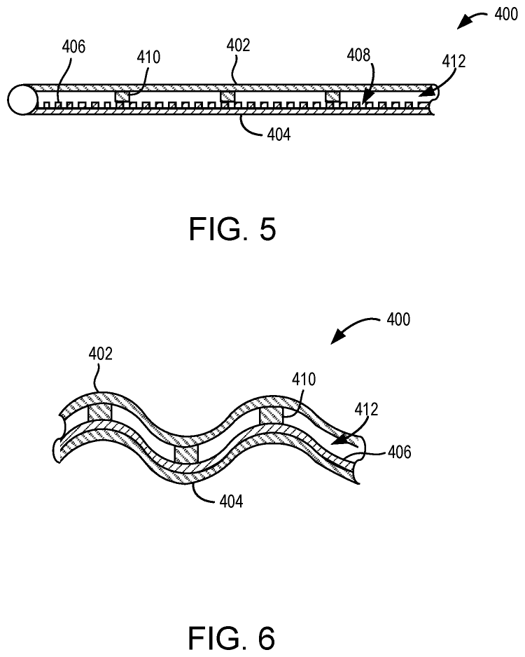

FIG. 5 shows a schematic sectional view of vapor chamber 400 in an assembled state, taken along line 5-5 of FIG. 4. As can be seen, the spacers 414 support the cross-sectional area of vapor chamber 502 without substantially impeding vapor flow in the vapor chamber. Further, third layer 504 and second layer 506 together form a wicking structure to enable liquid transport via capillary action. FIG. 6 shows another sectional view of vapor chamber 400 in an assembled state, taken along line 6-6 of FIG. 4. Here, it can be seen that spacers 414 support the vapor chamber in the corrugated hinge region to maintain a desired cross-sectional area as the corrugated area is flexed.

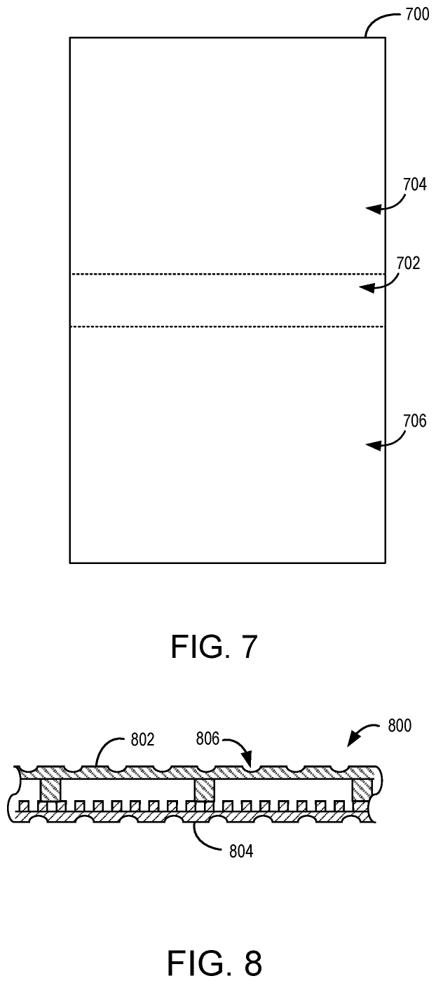

As mentioned above, in some examples, instead of using a corrugated structure in the flexible hinge region, a flexible hinge region may be formed from sheets of a Ni/Ti (Nitinol) alloy (e.g. 50 μm thick sheets). In some examples, a vapor chamber may be formed entirely from such an alloy. In other examples, a hinge region of the vapor chamber may be formed from such an alloy, and other regions of the vapor chamber may be formed from titanium metal. FIG. 7 shows a schematic depiction of a vapor chamber 700 comprising a hinge region 702 formed from a Ni/Ti, and an evaporator region 704 and a condenser region 706 each formed from titanium metal. The first, second and third layers of the titanium evaporator and condenser regions 704, 706 may be joined to the corresponding layers of the hinge region 702 via welds, as titanium metal can be joined to the Ni/Ti alloy via welding. The configuration of FIG. 7 may be less expensive to manufacture than a vapor chamber made fully of Ni/Ti alloy, as such alloys may cost more than titanium metal. It will be understood that the internal structure of vapor chamber 700 may be similar to that of vapor chamber 400, in that vapor chamber 700 may comprise wicking structures formed in the third layer, and also may comprise spacers to maintain a desired cross-sectional area within the vapor chamber of vapor chamber 700, both in the hinge region 702 and outside of the hinge region.

To enable a vapor chamber to flex through a wide range of configurations, the third layer may be configured to shear with respect to the other layers. For example, the third layer of vapor chambers 400 and/or 700 may attached to the first and/or second layer only at the condenser or evaporator end. This may make the overall structure easier to bend than if the third layer is welded around an entire perimeter to the first and/or second layer.

In some examples, other bending structures than corrugations may be used to form a flexible hinge region. FIG. 8 shows a schematic sectional view of another example vapor chamber 800 comprising a first layer 802 and a second layer 804 comprising one or more bending features in the form of etched depressions 806 that thin the titanium layer at locations along the hinge region of the vapor chamber 800. In some such examples, where the first layer 802 and second layer 804 have a thickness of 100 microns, the layers may be as thin as 30 μm or less in the etched depressions 806. In other examples, the first and second layers and the etched depressions 806 may have any other suitable thicknesses.

The flexible hinge region examples described above also may be configured to provide other functionalities besides heat transfer. For example, any of the examples described above may be configured to provide spring force to facilitate or resist movement of a hinge in a device. As a more specific example, a vapor chamber having a corrugated hinge region, when used in a laptop computer, may be configured to have a neutral spring force when the laptop is in the open configuration shown in FIG. 1, and to provide a bias toward the open configuration when the laptop computer is in the closed position of FIG. 2. This may facilitate moving the screen portion of the laptop computing device from the open to the closed position. Any of the example flexible hinge regions described above may be configured to provide any suitable bias toward any suitable hinge position based upon the device in which the vapor chamber is used.

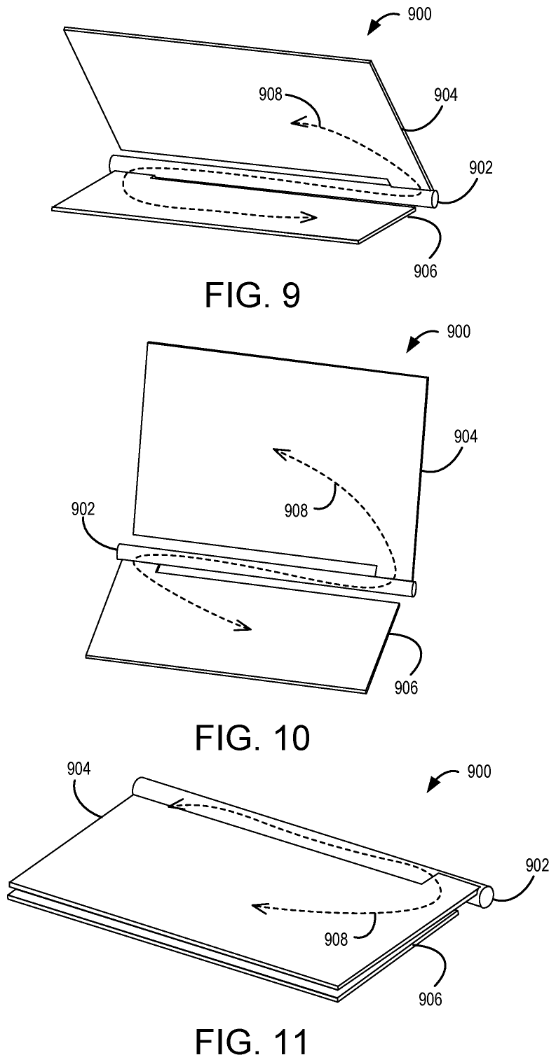

As mentioned above, in some examples a vapor chamber may comprise a torsional hinge structure configured to bridge a hinge region of a laptop computing device. FIGS. 9-11 show an example vapor chamber 900 comprising a torsional hinge structure 902 connecting a screen vapor chamber section 904 and a keyboard vapor chamber section 906. The vapor chamber 902 comprises an internal chamber that is continuous through the screen vapor chamber section 904, the keyboard vapor chamber section 906 and the torsional hinge structure 902. Further, a continuous wicking structure (not shown) extends between the screen vapor chamber section 904, the keyboard vapor chamber section 906 and the heat pipe 902. The continuous wicking structure may be formed from separate wick sections that are joined in some examples, and may be formed from any suitable material or materials, including conventional wicking materials as well as titanium-containing materials. Arrow 908 illustrates an example path for vapor and liquid flow between the first vapor chamber 904, the second vapor chamber 906 and the heat pipe 902.

The torsional hinge structure 902 may be configured to twist and undergo torsional deformation as the vapor chamber 900 moves between an open position and closed position. FIG. 9 shows the vapor chamber 900 in an example neutral position. FIG. 10 shows the vapor chamber in an example fully opened configuration screen portion 904 are oriented at an angle of approximately 120 degrees about the heat pipe 902. FIG. 11 shows the vapor chamber 900 in a fully closed configuration. As mentioned above, the vapor chamber maintains a flow path for the working fluid in the liquid and gas phases in each of these positions.

The torsional hinge 902 of the vapor chamber 900 may experience a degree of strain as it is moved toward the fully opened and closed positions. To help prevent fatigue-related failure over the lifetime of the device incorporating the vapor chamber 900, the torsional hinge 902 of the vapor chamber may comprise a highly elastic material, such as the Ni/Ti alloys discussed above. Forming the vapor chamber 900 to have a neutral amount of strain in a halfway-open configuration, as depicted in FIG. 9, may help to lessen the strain at the fully opened and fully closed positions.

Torque generated by torsion of the torsional hinge region 902 may compete with the hinge of a laptop device. As such, torque may be reduced by increasing a length of the torsional hinge region 902, adding bends, a coil, etc. Further, in some examples, torque may be reduced by reducing a radius of the heat pipe 902 or by changing a cross section shape of the heat pipe 902, with care taken to maintain desired liquid and vapor flow characteristics.

Another example provides an electronic device, comprising a first portion and a second portion connected by a hinge region, and a vapor chamber extending from the first portion to the second portion across the hinge region, the vapor chamber comprising a first layer comprising titanium, a second layer comprising titanium, the second layer being joined to the first layer to form the vapor chamber, a working fluid within the vapor chamber, and a third layer comprising titanium positioned between the first layer and the second layer, the third layer comprising one or more features configured to conduct the working fluid via capillary action. The electronic device may additionally or alternatively include a laptop computing device. The electronic device may additionally or alternatively include a head-mounted display device. The one or more features configured to conduct the working fluid via capillary action may additionally or alternatively include one or more etched channels. The electronic device may additionally or alternatively include one or more spacers configured to maintain separation between the first layer and the third layer. The vapor chamber may additionally or alternatively include a thickness of less than or equal to 500 μm. The vapor chamber may additionally or alternatively include a corrugated structure having a plurality of corrugations in the hinge region of the electronic device. Each corrugation of the plurality of corrugations may additionally or alternatively include a bend radius equal to or greater than ten times a thickness of the vapor chamber. The first layer, the second layer, and the third layer may each additionally or alternatively include a Ni/Ti alloy in the hinge region of the electronic device. The third layer may additionally or alternatively be configured to shear with respect to the first layer and the second layer. The third layer may additionally or alternatively be welded at one or more locations to one or more of the first layer and the second layer. The vapor chamber may additionally or alternatively include one or more etched bending features in one or more of the first layer and the second layer in the hinge region of the electronic device.

Another example provides a heat transfer device comprising a first titanium layer, a second titanium layer joined to the first layer to form a vapor chamber, a working fluid, and a third titanium layer positioned between the first layer and the second layer, the third titanium layer comprising one or more features configured to conduct the working fluid in a liquid phase via capillary action, wherein the heat transfer device comprises a flexible hinge region configured to flex while allowing vapors and fluids to flow through the vapor chamber. The one or more features configured to conduct the working fluid in the liquid phase via capillary action may additionally or alternatively include one or more etched channels. The heat transfer device may additionally or alternatively include one or more spacers positioned between the first layer and the third layer, wherein the one or more spacers are configured to maintain separation between the first layer and the third layer. The flexible hinge region may additionally or alternatively include a bend radius equal to or greater than ten times a thickness of the vapor chamber. The first layer, the second layer, and the third layer may each additionally or alternatively include a Ni/Ti alloy in the flexible hinge region.

Another example provides an electronic device, comprising a first portion and a second portion connected by a hinge region, and a vapor chamber extending from the first portion to the second portion, the vapor chamber comprising a torsional hinge connecting a first vapor chamber portion and a second vapor chamber portion. The vapor chamber may additionally or alternatively include a neutral position between a fully opened position and a fully closed position. The torsional hinge may additionally or alternatively include a Ni/Ti alloy.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. An electronic device, comprising:
a first portion and a second portion connected by a hinge region; and
a vapor chamber extending from the first portion to the second portion across the hinge region, the vapor chamber comprising
a first layer comprising titanium,
a second layer comprising titanium, the second layer being joined to the first layer to form the vapor chamber,
a working fluid within the vapor chamber; and
a third layer comprising titanium positioned between the first layer and the second layer, the third layer comprising one or more features configured to conduct the working fluid via capillary action.

2. The electronic device of claim 1, wherein the electronic device comprises a laptop computing device.

3. The electronic device of claim 1, wherein the electronic device comprises a head-mounted display device.

4. The electronic device of claim 1, wherein the one or more features configured to conduct the working fluid via capillary action comprise one or more etched channels.

5. The electronic device of claim 1, further comprising one or more spacers configured to maintain separation between the first layer and the third layer.

6. The electronic device of claim 1, wherein the vapor chamber has a thickness of less than or equal to 500 μm.

7. The electronic device of claim 1, wherein the vapor chamber comprises a corrugated structure having a plurality of corrugations in the hinge region of the electronic device.

8. The electronic device of claim 7, wherein each corrugation of the plurality of corrugations has a bend radius equal to or greater than ten times a thickness of the vapor chamber.

9. The electronic device of claim 1, wherein the first layer, the second layer, and the third layer each comprises a Ni/Ti alloy in the hinge region of the electronic device.

10. The electronic device of claim 1, wherein the third layer is configured to shear with respect to the first layer and the second layer.

11. The electronic device of claim 1, wherein the third layer is welded at one or more locations to one or more of the first layer and the second layer.

12. The electronic device of claim 1, wherein the vapor chamber comprises one or more etched bending features in one or more of the first layer and the second layer in the hinge region of the electronic device.

13. A heat transfer device comprising:
a first titanium layer;
a second titanium layer joined to the first layer to form a vapor chamber;
a working fluid; and
a third titanium layer positioned between the first layer and the second layer, the third titanium layer comprising one or more features configured to conduct the working fluid in a liquid phase via capillary action,
wherein the heat transfer device comprises a flexible hinge region configured to flex while allowing vapors and fluids to flow through the vapor chamber.

14. The heat transfer device of claim 13, wherein the one or more features configured to conduct the working fluid in the liquid phase via capillary action comprise one or more etched channels.

15. The heat transfer device of claim 13, further comprising one or more spacers positioned between the first layer and the third layer, wherein the one or more spacers are configured to maintain separation between the first layer and the third layer.

16. The heat transfer device of claim 13, wherein the flexible hinge region comprises a plurality of corrugation each having a bend radius equal to or greater than ten times a thickness of the vapor chamber.

17. The heat transfer device of claim 13, wherein the first layer, the second layer, and the third layer each comprises a Ni/Ti alloy in the flexible hinge region.

18. An electronic device, comprising:
a first portion and a second portion connected by a hinge region; and
a vapor chamber extending from the first portion to the second portion, the vapor chamber comprising a torsional hinge connecting a first vapor chamber portion and a second vapor chamber portion, the torsional hinge configured to twist and undergo torsional deformation while allowing vapors and fluids to flow through the vapor chamber.

19. The electronic device of claim 18, wherein the vapor chamber comprises a neutral position between a fully opened position and a fully closed position.

20. The electronic device of claim 18, wherein the torsional hinge comprises a Ni/Ti alloy.
